(19) United States
(12) Patent Application Publication
(10) Pub. No.: US 2025/0022695 A1
(43) Pub. Date: Jan. 16, 2025

(54) PLASMA PROCESSING APPARATUS, SUBSTRATE PROCESSING APPARATUS, AND TEMPERATURE CONTROL SYSTEM

(71) Applicant: Tokyo Electron Limited, Tokyo (JP)

(72) Inventor: Kazuki HOSHI, Miyagi (JP)

(21) Appl. No.: 18/768,441

(22) Filed: Jul. 10, 2024

(30) Foreign Application Priority Data
Jul. 12, 2023 (JP) 2023-114418
Jun. 5, 2024 (JP) 2024-091607

(51) Int. Cl. H01J 37/32; G05D 23/19; H01L 21/67

(52) U.S. Cl. CPC H01J 37/32724; G05D 23/1923; H01L 21/67017; H01J 2237/002; H01J 2237/2007

(57) ABSTRACT

A plasma processing apparatus includes a plasma process chamber; a substrate support that is disposed in the plasma process chamber and includes a first flow path; an upper electrode assembly that is disposed above the substrate support and includes a second flow path; a first chiller configured to maintain a temperature of a first temperature-controlled fluid at a first temperature, the first temperature-controlled fluid flowing through the first flow path; a second chiller configured to maintain a temperature of a second temperature-controlled fluid at a second temperature, the second temperature-controlled fluid flowing through the second flow path; and a thermoelectric element configured to generate power by a difference in temperature between the first temperature-controlled fluid and the second temperature-controlled fluid.

### CROSS-REFERENCE TO RELATED APPLICATIONS

This application is based upon and claims priority to Japanese Patent Application No. 2023-114418, filed on Jul. 12, 2023 and Japanese Patent Application No. 2024-091607, filed on Jun. 5, 2024, the entire contents of which are incorporated herein by reference.

### BACKGROUND

### 1. Field of the Invention

The present disclosure relates to plasma processing apparatuses, substrate processing apparatuses, and temperature control systems.

### 2. Description of the Related Art

Japanese Patent Application Publication No. 2019-192728 discloses a plasma processing apparatus including a lower electrode and an upper electrode. Also, Japanese Patent Application Publication No. 2019-192728 discloses that the temperature of a substrate W is adjusted by supplying a heat exchange medium from a chiller to a flow path in the lower electrode. In addition, Japanese Patent Application Publication No. 2019-192728 discloses that the upper electrode is cooled by supplying a coolant from a chiller to a flow path in the upper electrode.

### SUMMARY

According to an aspect of the present disclosure, a plasma processing apparatus includes: a plasma process chamber; a substrate support that is disposed in the plasma process chamber and includes a first flow path; an upper electrode assembly that is disposed above the substrate support and includes a second flow path; a first chiller configured to maintain a temperature of a first temperature-controlled fluid at a first temperature, the first temperature-controlled fluid flowing through the first flow path; a second chiller configured to maintain a temperature of a second temperature-controlled fluid at a second temperature, the second temperature-controlled fluid flowing through the second flow path; and a thermoelectric element configured to generate power by a difference in temperature between the first temperature-controlled fluid and the second temperature-controlled fluid.

### BRIEF DESCRIPTION OF THE DRAWINGS

FIG. 1 is a diagram describing a configuration example of a plasma processing system including a plasma processing apparatus according to the present embodiment;

FIG. 2 is a diagram describing an overview of a configuration of a plasma processing apparatus according to a first embodiment;

FIG. 3 is a diagram describing an overview of a configuration of a plasma processing apparatus according to a second embodiment;

FIG. 4 is a diagram describing an overview of a configuration of a plasma processing apparatus according to a third embodiment; and

FIG. 5 is a diagram describing an overview of the configuration of the plasma processing apparatus according to the third embodiment.

### DETAILED DESCRIPTION OF THE INVENTION

The present disclosure provides a technique of generating power in a plasma processing apparatus.

Hereinafter, the embodiments of the present disclosure will be described with reference to the drawings. In the present specification and the drawings, substantially the same components are designated by the same reference symbols, and thus duplicate description thereof is omitted. For ease of understanding, the scale of each part in the drawings may be different from the actual scale thereof. Regarding terms in relation to directions, such as parallel, the right angle, orthogonal, horizontal, vertical, upward and downward, leftward and rightward, and the like, deviation is acceptable to the extent that does not impair the effects of the embodiments. The shape of corners is not limited to the right angle and may be rounded. Being parallel, the right angle, orthogonal, horizontal, and vertical may include being approximately parallel, approximately the right angle, approximately orthogonal, approximately horizontal, and approximately vertical.

### Plasma Processing Apparatus According to the First Embodiment

### <Plasma Processing System>

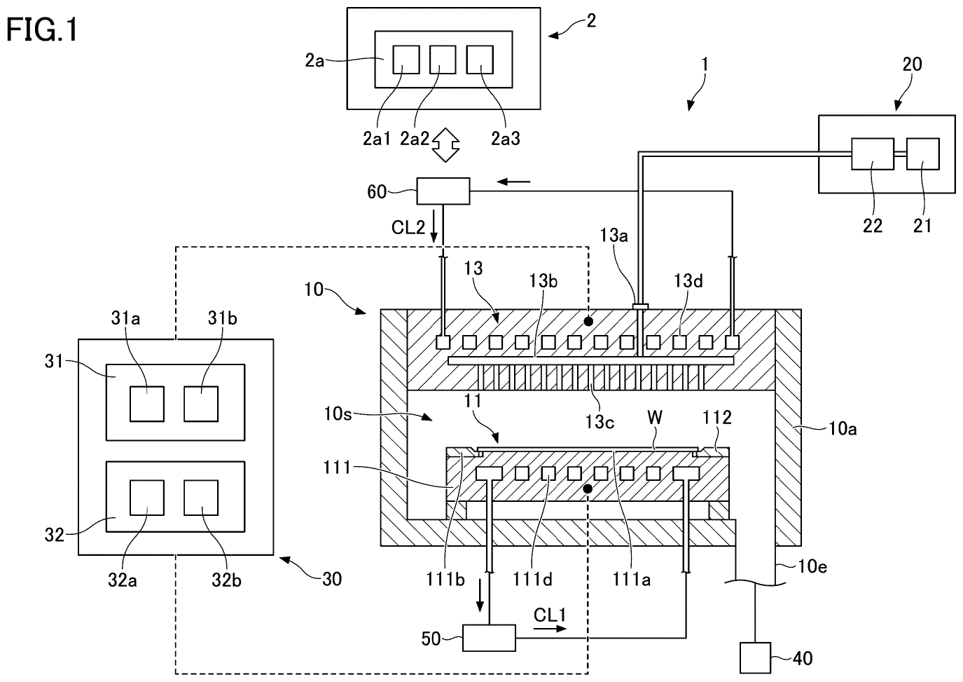

A configuration example of the plasma processing system will be described below. FIG. 1 is a diagram describing a configuration example of a plasma processing system including a capacitively coupled plasma processing apparatus 1 that is an example of the plasma processing apparatus according to the present embodiment.

The plasma processing system includes the capacitively coupled plasma processing apparatus 1 and a controller 2. The capacitively coupled plasma processing apparatus 1 includes a plasma process chamber 10, a gas supply 20, a power supply 30, and a gas exhaust system 40. Also, the plasma processing apparatus 1 includes a substrate support 11 and a gas introducer. The gas introducer is configured to introduce at least one process gas into the plasma process chamber 10. The gas introducer includes a shower head 13. The substrate support 11 is disposed in the plasma process chamber 10. The shower head 13 is disposed above the substrate support 11. In one embodiment, the shower head 13 forms at least a part of a ceiling of the plasma process chamber 10. The plasma process chamber 10 includes a plasma process space 10s defined by the shower head 13, a side wall 10a of the plasma process chamber 10, and the substrate support 11. The plasma process chamber 10 includes at least one gas supply port through which at least one process gas is supplied to the plasma process space 10s; and at least one gas exhaust port through which the gas is exhausted from the plasma process space 10s. The side wall 10a is grounded. The shower head 13 and the substrate support 11 are electrically insulated from a casing of the plasma process chamber 10.

The substrate support 11 includes a body 111 and a ring assembly 112. The body 111 includes a center region 111a (substrate support) on which a substrate (wafer) W is supported; and an annular region (ring support surface) 111b on which the ring assembly 112 is supported. The annular region 111b of the body 111 encloses the center region 111a of the body 111 in a plan view. The substrate W is disposed on the center region 111a of the body 111, and the ring assembly 112 is disposed on the annular region 111b of the body 111 so as to enclose the substrate W on the center region 111a of the body 111. In one embodiment, the body 111 includes a base and an electrostatic chuck. The base includes a conductive member. The conductive member of the base can function as a lower electrode. The electrostatic chuck is disposed on the base. The upper surface of the electrostatic chuck includes a substrate support surface 111a. The ring assembly 112 includes one or more annular members. At least one of the one or more annular members is an edge ring. Also, the body 111 includes a flow path 111d through which a temperature-controlled medium CL1 flows. The temperature-controlled medium CL1 is supplied from a temperature adjuster 50. The temperature adjuster 50 is configured to adjust the temperature of the temperature-controlled medium CL1 returned from the body 111 to a predetermined temperature and then supply the adjusted temperature-controlled medium CL1 to the body 111. The temperature-controlled medium CL1 is a heat transfer fluid, such as brine, gas, or the like. Although not illustrated, the substrate support 11 may include a temperature control module configured to control the electrostatic chuck, the ring assembly 112, the substrate, or any combination thereof, to the target temperature. The temperature control module may further include a heater, a heat transfer medium, or a combination thereof. Also, the substrate support 11 may include a heat transfer gas supply configured to supply a heat transfer gas between the back surface of the substrate W and the substrate support surface 111a.

The shower head 13 is configured to introduce at least one process gas from the gas supply 20 into the plasma process space 10s. The shower head 13 includes at least one gas supply port 13a, at least one gas diffusion chamber 13b, and multiple gas introducing ports 13c. The process gas supplied to the gas supply port 13a passes through the gas diffusion chamber 13b and is introduced into the plasma process space 10s from the multiple gas introducing ports 13c. Also, the shower head 13 includes a conductive member. The conductive member of the shower head 13 functions as an upper electrode. Further, the shower head 13 includes a flow path 13d through which a temperature-controlled medium CL2 flows. The temperature-controlled medium CL2 is supplied from a temperature adjuster 60. The temperature adjuster 60 is configured to adjust the temperature of the temperature-controlled medium CL2 returned from the shower head 13 to a predetermined temperature and then supply the adjusted temperature-controlled medium CL2 to the shower head 13. The temperature-controlled medium CL2 is a heat transfer fluid, such as brine, gas, or the like. The shower head 13 may be formed to include the upper electrode, a cooling plate, and the like. In addition to the shower head 13, the gas introducer may include one or more side gas injectors (SGI) attached to one or more openings formed in the side wall 10a.

The gas supply 20 may include at least one gas source 21 and at least one flow controller 22. In one embodiment, the gas supply 20 is configured to supply at least one process gas from a corresponding gas source 21 to the shower head 13 via a corresponding flow controller 22. The flow controller 22 may include, for example, a mass flow controller or a pressure-controlled flow controller. In addition, the gas supply 20 may include one or more flow rate modulators configured to pulse or modulate the flow rate of at least one process gas.

The power supply 30 includes an RF power supply 31 that is connected to the plasma process chamber 10 via at least one impedance matching circuit. The RF power supply 31 is configured to supply at least one RF signal (RF power), such as a source RF signal or a bias RF signal, to the conductive member of the substrate support 11, the conductive member of the shower head 13, or both. Thereby, plasma is formed from at least one process gas supplied to the plasma process space 10s. Thus, the RF power supply 31 may function as at least a part of a plasma generator configured to generate plasma from one or more process gases in the plasma process chamber 10. Also, by supplying a bias RF signal to the conductive member of the substrate support 11, a bias potential is generated in the substrate W, and ionic components in the formed plasma can be drawn into the substrate W.

In one embodiment, the RF power supply 31 includes a first RF generator 31a and a second RF generator 31b. The first RF generator 31a is connected to the conductive member of the substrate support 11, the conductive member of the shower head 13, or both via at least one impedance matching circuit and is configured to generate a source RF signal (source RF power) for generation of plasma. In one embodiment, the source RF signal has a frequency in the range of from 13 MHz through 150 MHz. In one embodiment, the first RF generator 31a may be configured to generate multiple source RF signals having different frequencies. The generated one or more source RF signals are supplied to the conductive member of the substrate support 11, the conductive member of the shower head 13, or both. The second RF generator 31b is connected to the conductive member of the substrate support 11 via at least one impedance matching circuit and is configured to generate a bias RF signal (bias RF power). In one embodiment, the bias RF signal has a frequency that is lower than the frequency of the source RF signal. In one embodiment, the bias RF signal has a frequency in the range of from 400 kHz through 13.56 MHz. In one embodiment, the second RF generator 31b may be configured to generate multiple bias RF signals having different frequencies. The generated one or more bias RF signals are supplied to the conductive member of the substrate support 11. Also, in various embodiments, the source RF signal, the bias RF signal, or both may be pulsed.

Also, the power supply 30 may include a DC power supply 32 that is connected to the plasma process chamber 10. The DC power supply 32 includes a first DC generator 32a and a second DC generator 32b. In one embodiment, the first DC generator 32a is connected to the conductive member of the substrate support 11 and is configured to generate a first DC signal. The generated first DC signal is applied to the conductive member of the substrate support 11. In one embodiment, the first DC signal may be applied to other electrodes, such as an electrode in the electrostatic chuck. In one embodiment, the second DC generator 32b is connected to the conductive member of the shower head 13 and is configured to generate a second DC signal. The generated second DC signal is applied to the conductive member of the shower head 13. In various embodiments, the first DC signal, the second DC signal, or both may be pulsed. The first and second DC generators 32a and 32b may be provided in addition to the RF power supply 31, and the first DC generator 32a may be provided instead of the second RF generator 31b.

The gas exhaust system 40 may be connected, for example, to a gas exhaust port 10e provided at the bottom of the plasma process chamber 10. The gas exhaust system 40 may include a pressure control valve and a vacuum pump. The pressure control valve adjusts the pressure in the plasma process space 10s. The vacuum pump may include a turbomolecular pump, a dry pump, or both.

The controller 2 is configured to process computer-executable instructions that cause the plasma processing apparatus 1 to perform various steps as described in the present disclosure. The controller 2 may be configured to control the components of the plasma processing apparatus 1 so as to perform the various steps as described herein. In one embodiment, a part of or the entirety of the controller 2 may be included in the plasma processing apparatus 1. The controller 2 may include a computer 2a and the like. The computer 2a may include a processor (central processing unit (CPU)) 2a1, a storage 2a2, and a communication interface 2a3. The processor 2a1 may be configured to perform various controls in accordance with a program stored in the storage 2a2. The storage 2a2 may include a RAM (Random Access Memory), a ROM (Read Only Memory), an HDD (Hard Disk Drive), an SSD (Solid State Drive), or any combination thereof. The communication interface 2a3 may communicate with the plasma processing apparatus 1 through a communication line, such as a LAN (Local Area Network) or the like.

The plasma processing apparatus according to the first embodiment will be described below. The plasma processing apparatus according to the first embodiment includes: an upper electrode including a first flow path through which a first temperature-controlled medium flows; and a lower electrode including a second flow path through which a second temperature-controlled medium flows. Also, the plasma processing apparatus according to the first embodiment includes: a first temperature adjuster configured to adjust the temperature of the first temperature-controlled medium returned from the first flow path to a first temperature and then supply the adjusted first temperature-controlled medium to the first flow path; and a second temperature adjuster configured to adjust the temperature of the second temperature-controlled medium returned from the second flow path to a second temperature and then supply the adjusted second temperature-controlled medium to the second flow path. Further, the plasma processing apparatus according to the first embodiment includes a power generator configured to generate power by a difference in temperature between the first temperature-controlled medium and the second temperature-controlled medium.

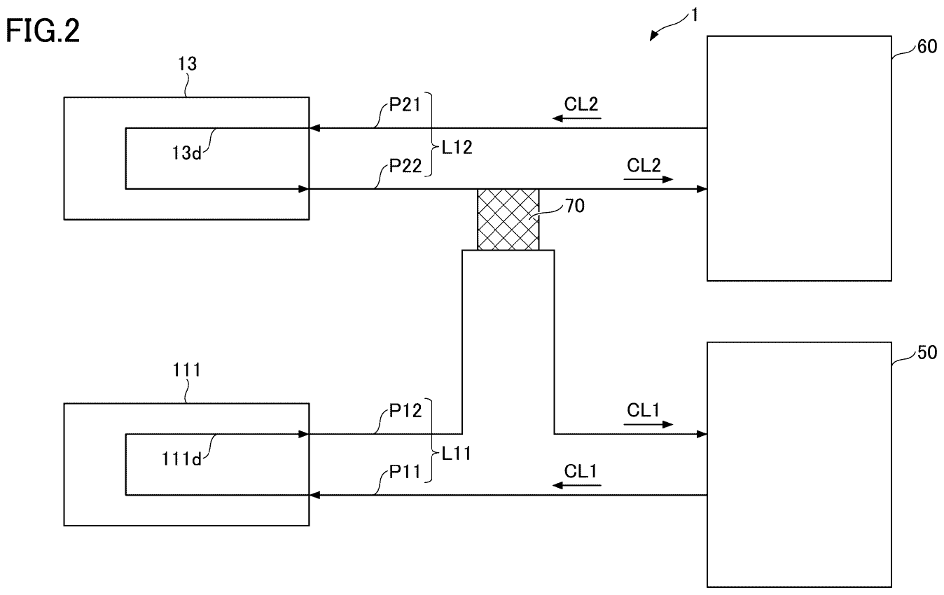

FIG. 2 is a diagram describing an overview of a configuration of the plasma processing apparatus 1 that is an example of the plasma processing apparatus according to the first embodiment.

The temperature adjuster 50 is configured to supply the temperature-controlled medium CL1, adjusted to a predetermined temperature, to the body 111 (lower electrode). Also, the temperature adjuster 50 recovers the temperature-controlled medium CL1 from the body 111. The temperature adjuster 50 adjusts the temperature of the recovered temperature-controlled medium CL1 to a predetermined temperature and then supplies the adjusted temperature-controlled medium CL1 to the body 111 again. The temperature-controlled medium CL1 circulates between the body 111 and the temperature adjuster 50.

The temperature adjuster 50 is configured to supply the temperature-controlled medium CL1 to the body 111 through a flow path P11. The temperature-controlled medium CL1 flowing out from the temperature adjuster 50 flows from the temperature adjuster 50 through the flow path P11 into the flow path 111d in the body 111.

The temperature adjuster 50 is configured to recover the temperature-controlled medium CL1 from the body 111 through a flow path P12. The temperature-controlled medium CL1 flowing through the flow path 111d in the body 111 passes through the flow path P12 and flows into the temperature adjuster 50. The flow path P11 and the flow path P12 may be collectively referred to as a circulation line L11. The circulation line L11 connects the temperature adjuster 50 and the flow path 111d in the body 111 such that a fluid flows between the temperature adjuster 50 and the flow path 111d.

The temperature adjuster 60 is configured to supply the temperature-controlled medium CL2, adjusted to a predetermined temperature, to the shower head 13 (upper electrode). Also, the temperature adjuster 60 recovers the temperature-controlled medium CL2 from the shower head 13. The temperature adjuster 60 adjusts the temperature of the recovered temperature-controlled medium CL2 to a predetermined temperature, and supplies the adjusted temperature-controlled medium CL2 to the shower head 13 again. The temperature-controlled medium CL2 circulates between the shower head 13 and the temperature adjuster 60.

The temperature adjuster 60 supplies the temperature-controlled medium CL2 to the shower head 13 through a flow path P21. The temperature-controlled medium CL2 flowing out from the temperature adjuster 60 flows from the temperature adjuster 60 through the flow path P21 into the flow path 13d in the shower head 13.

The temperature adjuster 60 is configured to recover the temperature-controlled medium CL2 from the shower head 13 through a flow path P22. The temperature-controlled medium CL2 flowing through the flow path 13d in the shower head 13 passes through the flow path P22 and then flows into the temperature adjuster 60. The flow path P21 and the flow path P22 may be collectively referred to as a circulation line L12. The circulation line L12 connects the temperature adjuster 60 and the flow path 13d in the shower head 13 such that a fluid flows between the temperature adjuster 60 and the flow path 13d.

The temperature adjuster 50 and the temperature adjuster 60 may perform temperature adjustment such that the temperature of the temperature-controlled medium CL2 becomes higher than the temperature of the temperature-controlled medium CL1. That is, the temperature of the temperature-controlled medium CL2 may be higher than the temperature of the temperature-controlled medium CL1. For example, the temperature adjuster 50 may adjust the temperature of the temperature-controlled medium CL1 to be lower than 30° C. (degrees Celsius), and the temperature adjuster 60 may adjust the temperature of the temperature-controlled medium CL2 to be in the range of from 80° C. through 150° C. Also, the temperature adjuster 50 may adjust the temperature of the temperature-controlled medium CL1 to be lower than −20° C., and the temperature adjuster 60 may adjust the temperature of the temperature-controlled medium CL2 to be higher than 80° C.

The flow path P11, the flow path P12, the flow path P21, and the flow path P22 are formed by a pipe, a hose, or the like.

The plasma processing apparatus 1 includes a power generator 70 between the flow path P12 and the flow path P22. The power generator 70 thermally contacts the flow path P12 and the flow path P22. Therefore, heat of the temperature-controlled medium CL1 in the flow path P12 and heat of the temperature-controlled medium CL2 in the flow path P22 are transferred to the power generator 70.

In the flow path P12 and the flow path P22, portions thereof connected to the power generator 70 may be formed of a member having high thermal conductivity, e.g., a metal, so as to achieve efficient transfer of the heat from the temperature-controlled medium CL1 or the temperature-controlled medium CL2. In the flow path P12 and the flow path P22, portions thereof connected to the power generator 70 may be coated with a heat conductive member, such as grease or the like.

The power generator 70 is configured to generate power by the difference in temperature between the temperature-controlled medium CL1 and the temperature-controlled medium CL2. The power generator 70 includes, for example, a thermoelectric conversion element configured to convert thermal energy to electric energy. The thermoelectric element is, for example, a Seebeck element. A Peltier element configured to transfer heat by electric energy may be used as the thermoelectric element.

The power generated by the power generator 70 may be supplied, for example, to the temperature adjuster 50 and the temperature adjuster 60, or may be stored in a power storage, such as a storage battery or the like.

According to the plasma processing apparatus according to the first embodiment, power can be generated by the difference in temperature between: the first temperature-controlled medium configured to control the temperature of the upper electrode; and the second temperature-controlled medium configured to control the temperature of the lower electrode. According to the plasma processing apparatus according to the first embodiment, power can be generated from waste heat by performing generation of power based on the difference in temperature between: the first temperature-controlled medium after controlling the temperature of the upper electrode; and the second temperature-controlled medium after controlling the temperature of the lower electrode. According to the plasma processing apparatus according to the first embodiment, it is possible to save power by generating power from waste heat.

In the above example, generation of power is performed by the difference in temperature between the temperature-controlled medium CL1 flowing through the flow path P12 and the temperature-controlled medium CL2 flowing through the flow path P22. However, a place where the power generator 70 is disposed is not limited to the above example as long as that place is where a difference in temperature occurs between the temperature-controlled medium CL1 and the temperature-controlled medium CL2.

In the plasma processing apparatus according to the first embodiment, the shower head 13 is an example of the upper electrode assembly, and the flow path 13d in the shower head 13 is an example of the second flow path. The temperature-controlled medium CL2 is an example of the second temperature-controlled fluid, the temperature adjuster 60 is an example of the second chiller or a second temperature controller, and the temperature at which the temperature adjuster 60 maintains the temperature-controlled medium CL2 is an example of the second temperature. The circulation line L12 is an example of a second circulation line or a second temperature control line.

The flow path 111d in the body 111 is an example of the first flow path. The temperature-controlled medium CL1 is an example of the first temperature-controlled fluid, the temperature adjuster 50 is an example of the first chiller or a first temperature controller, and the temperature at which the temperature adjuster 50 maintains the temperature-controlled medium CL1 is an example of the first temperature. The circulation line L11 is an example of a first circulation line or a first temperature control line.

Also, in the plasma processing apparatus according to the first embodiment, the temperature control system may be formed to include the first temperature control line, the second temperature control line, the first temperature controller, the second temperature controller, and the thermoelectric element. The plasma processing apparatus is an example of the substrate processing apparatus.

### Plasma Processing Apparatus According to the Second Embodiment

A plasma processing apparatus according to the second embodiment will be described below. The plasma processing apparatus according to the second embodiment is the same as the plasma processing apparatus according to the first embodiment except for including a first bypass flow path branched from the flow path through which the first temperature-controlled medium flows from the upper electrode to the first temperature adjuster. Also, the plasma processing apparatus according to the second embodiment is the same as the plasma processing apparatus according to the first embodiment except for including a second bypass flow path branched from the flow path through which the second temperature-controlled medium flows from the lower electrode to the second temperature adjuster. The plasma processing apparatus according to the second embodiment includes a power generator between the first bypass flow path and the second bypass flow path.

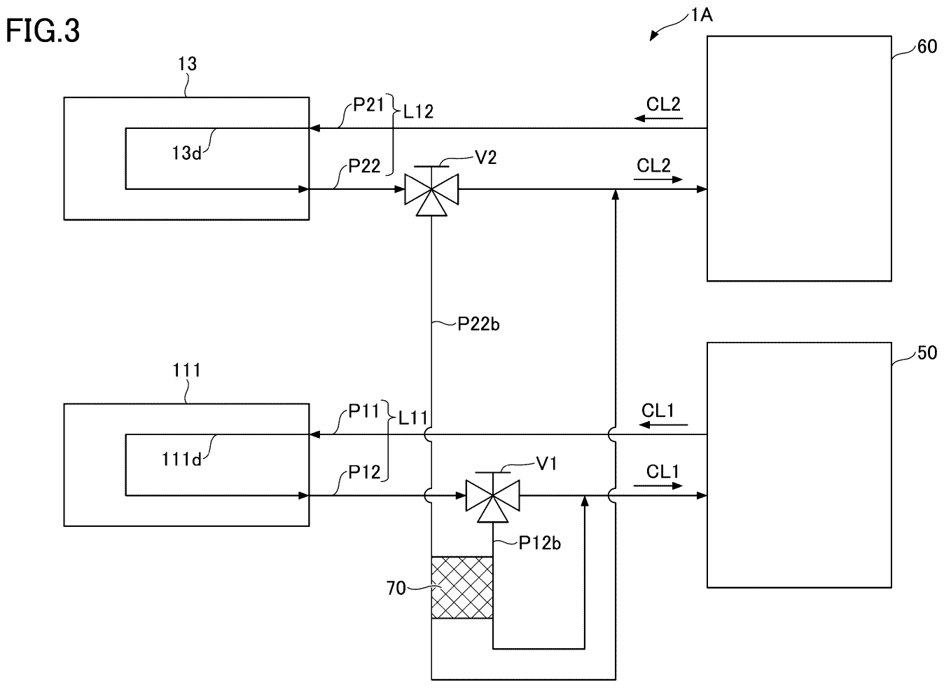

FIG. 3 is a diagram describing an overview of a configuration of a plasma processing apparatus 1A that is an example of the plasma processing apparatus according to the second embodiment. Detailed description of some components of the plasma processing apparatus 1A that are the same as the components of the plasma processing apparatus 1 is omitted, as reference is made to the detailed description of the plasma processing apparatus 1.

The plasma processing apparatus 1A includes a three-way valve V1 in the flow path P12 through which the temperature-controlled medium CL1 flows from the body 111 (lower electrode) toward the temperature adjuster 50. The plasma processing apparatus 1A includes a bypass flow path P12b that is branched via the three-way valve V1 and merges with the flow path P12 downstream.

Also, the plasma processing apparatus 1A includes a three-way valve V2 in the flow path P22 through which the temperature-controlled medium CL2 flows from the shower head 13 (upper electrode) toward the temperature adjuster 60. The plasma processing apparatus 1A includes a bypass flow path P22b that is branched via the three-way valve V2 and merges with the flow path P22 downstream.

The plasma processing apparatus 1A includes a power generator 70 between the bypass flow path P12b and the bypass flow path P22b. The power generator 70 thermally contacts the bypass flow path P12b and the bypass flow path P22b. Therefore, heat of the temperature-controlled medium CL1 in the bypass flow path P12b and heat of the temperature-controlled medium CL2 in the bypass flow path P22b are transferred to the power generator 70.

According to the plasma processing apparatus according to the second embodiment, power can be generated by the difference in temperature between: the first temperature-controlled medium configured to control the temperature of the upper electrode; and the second temperature-controlled medium configured to control the temperature of the lower electrode. According to the plasma processing apparatus according to the second embodiment, power can be generated from exhausted heat by performing generation of power based on the difference in temperature between: the first temperature-controlled medium after controlling the temperature of the upper electrode; and the second temperature-controlled medium after controlling the temperature of the lower electrode. According to the plasma processing apparatus according to the second embodiment, it is possible to save power by generating power from exhausted heat. According to the plasma processing apparatus according to the second embodiment, in which the power generator is provided between the bypass flow paths, it is possible to increase the degree of freedom in relation to a place where the power generator is disposed.

In the plasma processing apparatus according to the second embodiment, the bypass flow path P22b is an example of a second branch line, and the bypass flow path P12b is an example of a first branch line.

### Plasma Processing Apparatus According to the Third Embodiment

A plasma processing apparatus according to the third embodiment will be described below. The plasma processing apparatus according to the third embodiment includes: a lower electrode including a flow path through which a temperature-controlled medium flows; a first temperature adjuster configured to adjust the temperature of the temperature-controlled medium to a first temperature; and a second temperature adjuster configured to adjust the temperature of the temperature-controlled medium to a second temperature. Also, the plasma processing apparatus according to the third embodiment further includes: a connector configured to connect the flow path with the first temperature adjuster and the second temperature adjuster; and a power generator configured to generate power by a difference in temperature between the temperature-controlled medium returned to the first temperature adjuster and the temperature-controlled medium returned to the second temperature adjuster.

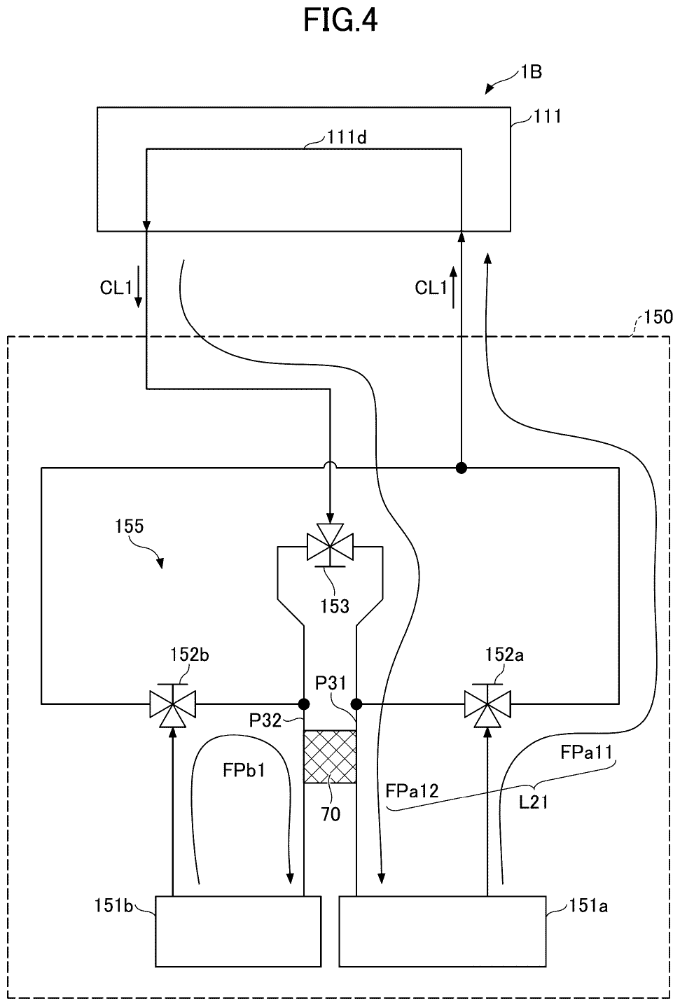

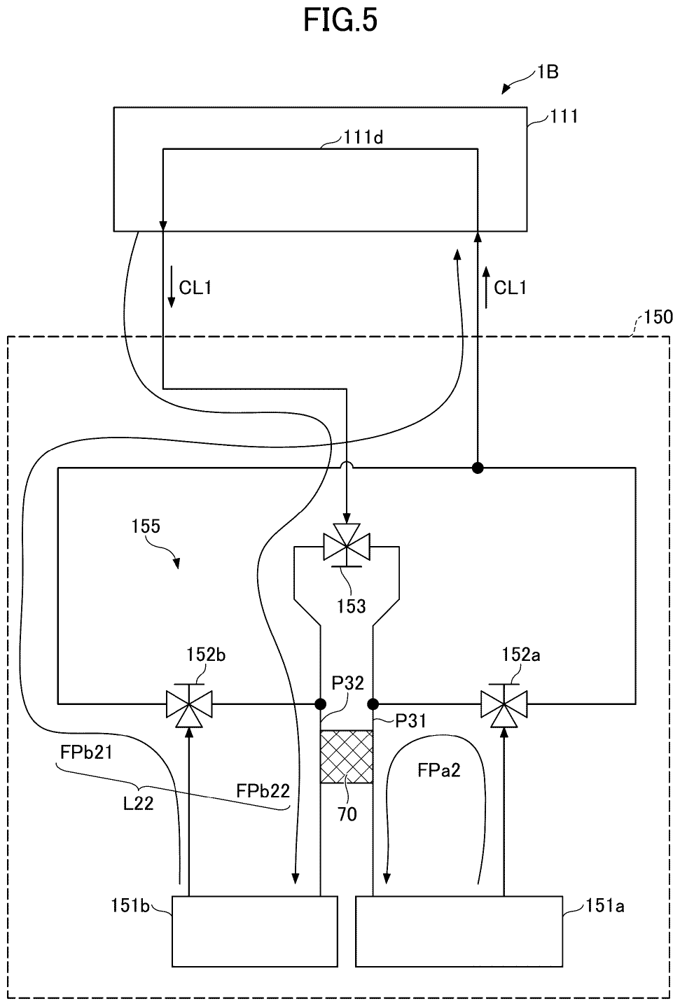

FIGS. 4 and 5 are diagrams describing an overview of a configuration of a plasma processing apparatus 1B that is an example of the plasma processing apparatus according to the third embodiment.

The plasma processing apparatus 1B includes a temperature-controlled medium supply 150 instead of the temperature adjuster 50 in the plasma processing apparatus 1.

The temperature-controlled medium supply 150 is configured to supply the temperature-controlled medium CL1, adjusted to a predetermined temperature, to the body 111 (lower electrode). Also, the temperature-controlled medium supply 150 recovers the temperature-controlled medium CL1 from the body 111. The temperature-controlled medium supply 150 adjusts the temperature of the recovered temperature-controlled medium CL1 to a predetermined temperature and then supplies the adjusted temperature-controlled medium CL1 to the body 111 again. The temperature-controlled medium CL1 circulates between the body 111 and the temperature-controlled medium supply 150.

The temperature-controlled medium supply 150 includes: a temperature adjuster 151a configured to adjust the temperature of the temperature-controlled medium CL1 to a temperature T1; and a temperature adjuster 151b configured to adjust the temperature of the temperature-controlled medium CL1 to a temperature T2. The temperature-controlled medium supply 150 includes the connector 155 configured to connect the temperature adjusters 151a and 151b with the flow path 111d in the body 111. The connector 155 includes a three-way valve 152a, a three-way valve 152b, and a three-way valve 153. For example, the temperature T2 may be higher than the temperature T1. The temperature T1 may be lower than −20° C., and the temperature T2 may be higher than 30° C.

First, a case (first mode) in which the temperature-controlled medium supply 150 supplies the temperature-controlled medium CL1 having the temperature T1 to the body 111 will be described with reference to FIG. 4.

When the temperature-controlled medium supply 150 supplies the temperature-controlled medium CL1 having the temperature T1 to the body 111, the temperature-controlled medium supply 150 switches the three-way valve 152a such that the temperature-controlled medium CL1 flows from the temperature adjuster 151a to the body 111. In FIG. 4, an arrowed line FPa11 indicates a path through which the temperature-controlled medium CL1 flows from the temperature adjuster 151a to the body 111.

The temperature-controlled medium supply 150 switches the three-way valve 152b such that the temperature-controlled medium CL1 is returned from the temperature adjuster 151b to the temperature adjuster 151b. In FIG. 4, an arrowed line FPb1 indicates a path through which the temperature-controlled medium CL1 flows from the temperature adjuster 151b back to the temperature adjuster 151b.

Further, the temperature-controlled medium supply 150 switches the three-way valve 153 such that the temperature-controlled medium CL1 flows from the body 111 to the temperature adjuster 151a. In FIG. 4, an arrowed line FPa12 indicates a path through which the temperature-controlled medium CL1 flows from the body 111 to the temperature adjuster 151a.

The flow paths indicated by the arrowed line FPa11 and the arrowed line FPa12 may be referred to as a supply line L21. The flow path indicated by the arrowed line FPb1 may be referred to as a circulation line.

Next, a case (second mode) in which the temperature-controlled medium supply 150 supplies the temperature-controlled medium CL1 having the temperature T2 to the body 111 will be described with reference to FIG. 5.

When the temperature-controlled medium supply 150 supplies the temperature-controlled medium CL1 having the temperature T2 to the body 111, the temperature-controlled medium supply 150 switches the three-way valve 152a such that the temperature-controlled medium CL1 is returned from the temperature adjuster 151a to the temperature adjuster 151a. In FIG. 5, an arrowed line FPa2 indicates a path in which the temperature-controlled medium CL1 flows from the temperature adjuster 151a back to the temperature adjuster 151a.

The temperature-controlled medium supply 150 switches the three-way valve 152b such that the temperature-controlled medium CL1 flows from the temperature adjuster 151b to the body 111. In FIG. 5, an arrowed line FPb21 indicates a path in which the temperature-controlled medium CL1 flows from the temperature adjuster 151b to the body 111.

Further, the temperature-controlled medium supply 150 switches the three-way valve 153 such that the temperature-controlled medium CL1 flows from the body 111 to the temperature adjuster 151b. In FIG. 5, an arrowed line FPb22 indicates a path in which the temperature-controlled medium CL1 flows from the body 111 to the temperature adjuster 151b.

The flow paths indicated by the arrowed line FPb21 and the arrowed line FPb22 may be referred to as a supply line L22. The flow path indicated by the arrowed line FPa2 may be referred to as a circulation line.

The plasma processing apparatus 1B includes the power generator 70 between: the flow path P31 through which the temperature-controlled medium CL1 is returned to the temperature adjuster 151a; and the flow path P32 through which the temperature-controlled medium CL1 is returned to the temperature adjuster 151b. The power generator 70 thermally contacts the flow path P31 and the flow path P32. Therefore, heat of the temperature-controlled medium CL1 in the flow path P31 and heat of the temperature-controlled medium CL1 in the flow path P32 are transferred to the power generator 70.

The power generator 70 is configured to generate power by the difference in temperature between: the temperature-controlled medium CL1 returned to the temperature adjuster 151a; and the temperature-controlled medium CL1 returned to the temperature adjuster 151b.

The controller included in the plasma processing apparatus 1B switches the three-way valve 152a, the three-way valve 152b, and the three-way valve 153, thereby performing control to establish the supply line and the circulation line in the first and second modes.

According to the plasma processing apparatus according to the third embodiment, power can be generated by using the temperature-controlled medium that controls the temperature of the lower electrode, and the difference in temperature between the temperature-controlled media returned to the two temperature adjusters. According to the plasma processing apparatus according to the third embodiment, power is generated from waste heat by the difference in temperature between the temperature-controlled media returned to the two temperature adjusters. According to the plasma processing apparatus according to the third embodiment, it is possible to save power by generating power from waste heat. Furthermore, according to the plasma processing apparatus according to the third embodiment, it is possible to reduce pipe routing and thus reduce the area of a site required for disposing the power generator.

In the plasma processing apparatus according to the third embodiment, the plasma process chamber 10 is an example of the chamber, the temperature-controlled medium CL1 is an example of the first temperature-controlled fluid or the second temperature-controlled fluid, and the flow path 111d in the body 111 is an example of an internal flow path. Also, the temperature adjuster 151a is an example of the first chiller, the temperature T1 is an example of the first temperature, the temperature adjuster 151b is an example of the second chiller, and the temperature T2 is an example of the second temperature. The three-way valve 152a, the three-way valve 152b, and the three-way valve 153 are examples of multiple valves. The supply line L21 is an example of a first supply line, the supply line L22 is an example of a second supply line, the flow path indicated by the arrowed line FPb1 is an example of the first circulation line, and the flow path indicated by the arrowed line FPa2 is an example of the second circulation line.

The plasma processing apparatus according to the present embodiment disclosed herein should be construed to be illustrative in all respects and not restrictive. The above embodiments may be modified and improved in various forms without departing from the scope and the subject of the claims recited. The matters described in the above embodiments can take other configurations to the extent that there is no contradiction, and can be combined together to the extent that there is no contradiction.

The present disclosure provides a technology of generating power in the plasma processing apparatus.

The above-described embodiments include, for example, the following.

### Clause 1

A plasma processing apparatus, including:

an upper electrode including a first flow path through which a first temperature-controlled medium flows;

a lower electrode including a second flow path through which a second temperature-controlled medium flows;

a first temperature adjuster configured to adjust a temperature of the first temperature-controlled medium returned from the first flow path to a first temperature, and supply the adjusted first temperature-controlled medium to the first flow path;

a second temperature adjuster configured to adjust a temperature of the second temperature-controlled medium returned from the second flow path to a second temperature, and supply the adjusted second temperature-controlled medium to the second flow path; and

a power generator configured to generate power by a difference in temperature between the first temperature-controlled medium and the second temperature-controlled medium.

In the plasma processing apparatus according to the first embodiment, the shower head 13 is an example of the upper electrode, and the flow path 13d in the shower head 13 is an example of the first flow path. Also, the temperature-controlled medium CL2 is an example of the first temperature-controlled medium, the temperature adjuster 60 is an example of the first temperature adjuster, and the predetermined temperature of the temperature-controlled medium CL2 adjusted by the temperature adjuster 60 is an example of the first temperature.

Also, the body 111 is an example of the lower electrode, and the flow path 111d in the body 111 is an example of the second flow path. The temperature-controlled medium CL1 is an example of the second temperature-controlled medium, the temperature adjuster 50 is an example of the second temperature adjuster, and the predetermined temperature of the temperature-controlled medium CL1 adjusted by the temperature adjuster 50 is an example of the second temperature.

### Clause 2

The plasma processing apparatus as described in clause 1, in which

the power generator is provided between
a first bypass flow path branched from a flow path through which the first temperature-controlled medium flows from the upper electrode to the first temperature adjuster, and
a second bypass flow path branched from a flow path through which the second temperature-controlled medium flows from the lower electrode to the second temperature adjuster.

In the plasma processing apparatus according to the second embodiment, the bypass flow path P22b is an example of the first bypass flow path, and the bypass flow path P12b is an example of the second bypass flow path.

### Clause 3

A plasma processing apparatus, including:

a lower electrode including a flow path through which a temperature-controlled medium flows;

a first temperature adjuster configured to adjust a temperature of the temperature-controlled medium to a first temperature;

a second temperature adjuster configured to adjust a temperature of the temperature-controlled medium to a second temperature;

a connector configured to connect the flow path with the first temperature adjuster and the second temperature adjuster; and

a power generator configured to generate power by a difference in temperature between the temperature-controlled medium returned to the first temperature adjuster and the temperature-controlled medium returned to the second temperature adjuster.

In the plasma processing apparatus according to the third embodiment, the temperature-controlled medium CL1 is an example of the temperature-controlled medium, the body 111 is an example of the lower electrode, and the flow path 111d in the body 111 is an example of the flow path. Also, the temperature adjuster 151a is an example of the first temperature adjuster, the temperature T1 is an example of the first temperature, the temperature adjuster 151b is an example of the second temperature adjuster, and the temperature T2 is an example of the second temperature.

What is claimed is:

1. A plasma processing apparatus, comprising:
a plasma process chamber;
a substrate support that is disposed in the plasma process chamber and includes a first flow path;
an upper electrode assembly that is disposed above the substrate support and includes a second flow path;
a first chiller configured to maintain a temperature of a first temperature-controlled fluid at a first temperature, the first temperature-controlled fluid flowing through the first flow path;
a second chiller configured to maintain a temperature of a second temperature-controlled fluid at a second temperature, the second temperature-controlled fluid flowing through the second flow path; and
a thermoelectric element configured to generate power by a difference in temperature between the first temperature-controlled fluid and the second temperature-controlled fluid.

2. The plasma processing apparatus according to claim 1, further comprising:
a first circulation line that connects the first chiller and the first flow path such that a fluid flows between the first chiller and the first flow path; and
a second circulation line that connects the second chiller and the second flow path such that a fluid flows between the second chiller and the second flow path, wherein
the thermoelectric element is disposed between the first circulation line and the second circulation line.

3. The plasma processing apparatus according to claim 1, further comprising:
a first circulation line that connects the first chiller and the first flow path such that a fluid flows between the first chiller and the first flow path;
a second circulation line that connects the second chiller and the second flow path such that a fluid flows between the second chiller and the second flow path;
a first branch line branched from the first circulation line; and
a second branch line branched from the second circulation line, wherein
the thermoelectric element is disposed between the first branch line and the second branch line.

4. The plasma processing apparatus according to claim 1, wherein
the second temperature is higher than the first temperature.

5. The plasma processing apparatus according to claim 4, wherein
the first temperature is lower than 30° C., and
the second temperature is in a range of from 80° C. through 150° C.

6. The plasma processing apparatus according to claim 4, wherein
the first temperature is lower than −20° C.

7. The plasma processing apparatus according to claim 6, wherein
the second temperature is higher than 80° C.

8. The plasma processing apparatus according to claim 1, wherein
the substrate support includes
a base, and
an electrostatic chuck, and
the first flow path is formed in the base.

9. The plasma processing apparatus according to claim 1, wherein
the upper electrode assembly includes
an upper electrode, and
a cooling plate, and
the second flow path is formed in the cooling plate.

10. The plasma processing apparatus according to claim 1, further comprising:
a power storage that is electrically connected to the thermoelectric element.

11. A substrate processing apparatus, comprising:
a chamber;
a substrate support that is disposed in the chamber and includes an internal flow path;
a first chiller configured to maintain a first temperature-controlled fluid at a first temperature;
a second chiller configured to maintain a second temperature-controlled fluid at a second temperature;
multiple valves;
a controller that is configured to perform switching of the multiple valves, and includes a processor and a memory storing one or more programs, which when executed, cause the processor to:
control the multiple valves, in a first mode, so as to establish a first supply line that circulates the first temperature-controlled fluid between the internal flow path and the first chiller, and establish a first circulation line that circulates the second temperature-controlled fluid between at least one of the multiple valves and the second chiller, and
control the multiple valves, in a second mode, so as to establish a second circulation line that circulates the first temperature-controlled fluid between at least one of the multiple valves and the first chiller, and establish a second supply line that circulates the second temperature-controlled fluid between the internal flow path and the second chiller; and
a thermoelectric element that is disposed
between the first supply line and the first circulation line,
between the second circulation line and the second supply line, or
both between the first supply line and the first circulation line and between the second circulation line and the second supply line.

12. The substrate processing apparatus according to claim 11, wherein
the second temperature is higher than the first temperature.

13. The substrate processing apparatus according to claim 12, wherein
the first temperature is lower than −20° C.

14. The substrate processing apparatus according to claim 13, wherein
the second temperature is higher than 30° C.

15. The substrate processing apparatus according to claim 11, wherein
the substrate support includes
a base, and
an electrostatic chuck, and
the internal flow path is formed in the base.

16. The substrate processing apparatus according to claim 11, further comprising:
a power storage that is electrically connected to the thermoelectric element.

17. A temperature control system, comprising:
a first temperature control line;
a second temperature control line;
a first temperature controller configured to maintain a temperature of a first temperature-controlled medium at a first temperature, the first temperature-controlled medium flowing through the first temperature control line;
a second temperature controller configured to maintain a temperature of a second temperature-controlled medium at a second temperature, the second temperature-controlled medium flowing through the second temperature control line; and
a thermoelectric element that is disposed between the first temperature control line and the second temperature control line.

18. The temperature control system according to claim 17, wherein
the thermoelectric element is configured to generate power by a difference in temperature between the first temperature-controlled medium and the second temperature-controlled medium.

19. The temperature control system according to claim 17, wherein
the thermoelectric element is a Seebeck element.
